(19) United States
(12) Patent Application Publication
(10) Pub. No.: US 2012/0206662 A1
(43) Pub. Date: Aug. 16, 2012

(54) TELEVISION AND ELECTRONIC APPARATUS

(75) Inventors: Seiji Hashimoto, Ome-shi (JP); Tomohiro Hamada, Tachikawa-shi (JP)

(73) Assignee: KABUSHIKI KAISHA TOSHIBA, Tokyo (JP)

(21) Appl. No.: 13/271,918

(22) Filed: Oct. 12, 2011

(30) Foreign Application Priority Data
Feb. 14, 2011 (JP) 2011-028704

(51) Int. Cl. H04N 5/64; H05K 5/00

(52) U.S. Cl. 348/836; 361/679.01; 348/E05.128

(57) ABSTRACT

According to one embodiment, an electronic apparatus including a housing, a cover, and a protrusion. The housing includes an accommodating portion configured to be exposed to an outside and accommodate a module. The accommodating portion includes a wall extending in a thickness direction of the housing. The cover is configured to cover the accommodating portion and includes a first surface exposed to the outside and a second surface opposite the first surface. The protrusion is on the second surface and is configured to touch the housing at a location adjacent to the wall.

### CROSS-REFERENCE TO RELATED APPLICATIONS

This application is based upon and claims the benefit of priority from prior Japanese Patent Application No. 2011-028704, filed Feb. 14, 2011, the entire contents of which are incorporated herein by reference.

### FIELD

Embodiments described herein relate generally to televisions and electronic apparatuses.

### BACKGROUND

An electronic apparatus comprising an accommodating portion for a hard disk drive (HDD) is known.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary plan view of an electronic apparatus according to a first embodiment;

FIG. 2 is an exemplary perspective view illustrating a lower wall of a main unit of the electronic apparatus illustrated in FIG. 1;

FIG. 3 is an exemplary plan view illustrating an HDD accommodating portion of the electronic apparatus illustrated in FIG. 2;

FIG. 4 is an exemplary plan view illustrating a state where the cover of the HDD accommodating portion illustrated in FIG. 3 is removed;

FIG. 5 is an exemplary perspective view of an HDD unit illustrated in FIG. 4;

FIG. 6 is an exemplary plan view illustrating a state where the HDD unit of the HDD accommodating portion illustrated in FIG. 4 is removed;

FIG. 7 is an exemplary perspective view illustrating a part of the HDD accommodating portion illustrated in FIG. 6;

FIG. 8 is an exemplary cross-sectional view of the HDD accommodating portion taken along the line F8-F8 in FIG. 6;

FIG. 9 is an exemplary cross-sectional view of the HDD accommodating portion taken along the line F9-F9 in FIG. 3;

FIG. 10 is an exemplary perspective view illustrating the inner surface of the cover illustrated in FIG. 3;

FIG. 11 is an exemplary cross-sectional view of the HDD accommodating portion taken along the line F11-F11 in FIG. 3;

FIG. 12 is an exemplary plan view illustrating a second surface of the cover illustrated in FIG. 3;

FIG. 13 is an exemplary perspective view illustrating the rear surface of a receiving portion illustrated in FIG. 7;

FIG. 14 is an exemplary cross-sectional view illustrating a first modification of the electronic apparatus illustrated in FIG. 1;

FIG. 15 is an exemplary cross-sectional view illustrating a second modification of the electronic apparatus illustrated in FIG. 1;

FIG. 16 is an exemplary cross-sectional view illustrating a third modification of the electronic apparatus illustrated in FIG. 1;

FIG. 17 is an exemplary cross-sectional view illustrating a fourth modification of the electronic apparatus illustrated in FIG. 1; and

FIG. 18 is an exemplary perspective view of a television according to a second embodiment.

### DETAILED DESCRIPTION

Various embodiments will be described hereinafter with reference to the accompanying drawings.

In general, according to one embodiment, an electronic apparatus comprising a housing, a cover, and a protrusion. The housing comprises an accommodating portion configured to be exposed to an outside and accommodate a module. The accommodating portion comprises a wall extending in a thickness direction of the housing. The cover is configured to cover the accommodating portion and comprises a first surface exposed to the outside and a second surface opposite the first surface. The protrusion is on the second surface and is configured to touch the housing at a location adjacent to the wall.

Hereinafter, embodiments will be described with reference to the drawings.

### First Embodiment

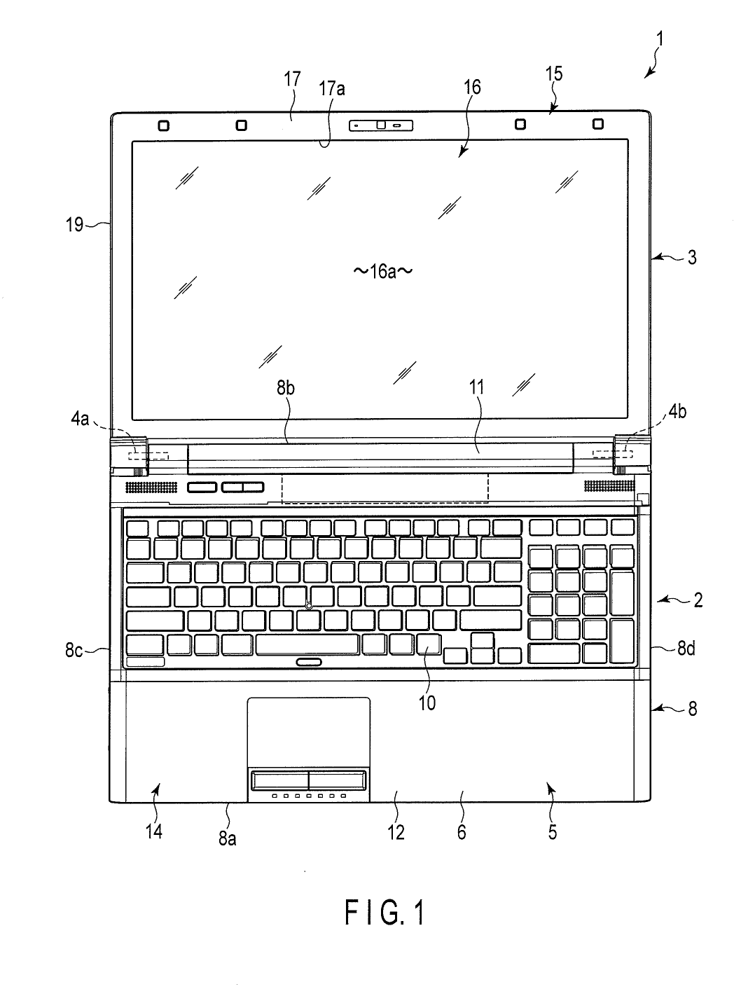

FIGS. 1 to 17 disclose an electronic apparatus 1 according to a first embodiment. The electronic apparatus 1 is a notebook-type portable computer (notebook PC), for example. The electronic apparatus to which the present embodiment can be applied is not limited to the above example, but can be broadly applied to various electronic apparatuses, such as a television, a slate-type portable computer (slate PC), a cellular phone, a smart phone, a personal digital assistant (PDA), and a game machine.

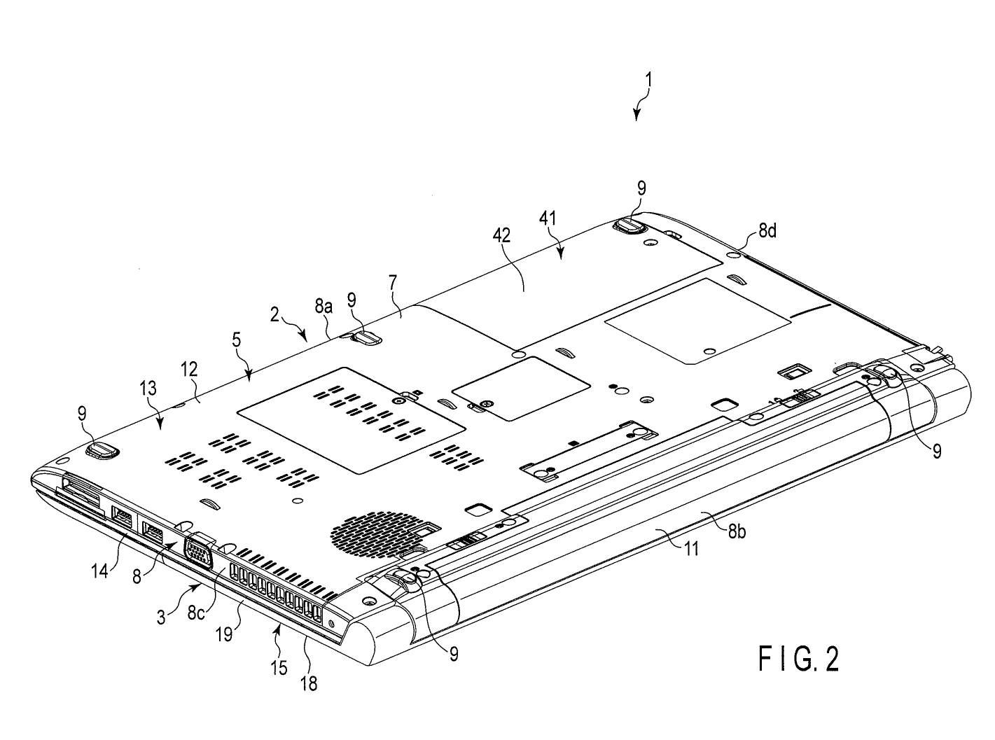

As illustrated in FIGS. 1 and 2, the electronic apparatus 1 includes a main unit 2 (first unit), a display unit 3 (second unit), and hinges 4a and 4b. The main unit 2 is an electronic apparatus body having a main board mounted therein. The main unit 2 includes a first housing 5. The first housing 5 includes an upper wall 6, a lower wall 7, and a circumferential wall 8 and has a flat box-like shape.

The lower wall 7 faces the surface of a desk when the electronic apparatus 1 is placed on the desk. The lower wall 7 includes a plurality of legs 9 that contact the desk surface and support the electronic apparatus 1. The upper wall 6 extends substantially in parallel to the lower wall 7 with a space between the lower wall 7 and the upper wall 6. A keyboard 10 is attached to the upper wall 6. The keyboard 10 is an example of an “input portion” (input receiving portion). In addition, the “input portion” may be a touch panel-type input device and may be other input devices.

The circumferential wall 8 stands on the lower wall 7 and connects the edge of the lower wall 7 and the edge of the upper wall 6. In addition, the circumferential wall 8 and the lower wall 7 may be continuous in a curved surface shape, for example, with no distinct boundary between them. At least part of the circumferential wall 8 extends in the thickness direction of the first housing 5. In the present embodiment, the direction extending from the upper wall 6 toward the lower wall 7 is the “thickness direction of the housing 5.”

The first housing 5 includes a rear end portion 11 (first end portion) and a front end portion 12 (second end portion). The display unit 3 is attached to the rear end portion 11 by the hinges 4a and 4b. The front end portion 12 is disposed opposite to the rear end portion 11.

The circumferential wall 8 includes a front wall 8a, a rear wall 8b, a left side wall 8c, and a right side wall 8d. The front wall 8a is located in the front end portion 12 of the first housing 5 so as to extend in a horizontal width direction (left and right direction) of the first housing 5. The rear wall 8b is located in the rear end portion 11 so as to extend in the horizontal width direction of the first housing 5 substantially in parallel to the front wall 8a. The left and right side walls 8c and 8d extend in a vertical width direction (front and rear direction) of the first housing 5. The left side wall 8c and the right side wall 8d connect the end portions of the front wall 8a and the end portions of the rear wall 8b, respectively.

As illustrated in FIG. 2, the first housing 5 includes a base 13 (first housing member) and a cover 14 (second housing member). The base 13 includes the lower wall 7 and part of the circumferential wall 8. The cover 14 includes the upper wall 6 and part of the circumferential wall 8. The cover 14 is combined with the base 13 to thereby form the first housing 5.

As illustrated in FIG. 1, the display unit 3 includes a second housing 15 and a display device 16 accommodated in the second housing 15. The display device 16 is a liquid crystal display, for example, but is not limited to this. The display device 16 includes a display screen 16a on which images and videos are displayed.

The second housing 15 is pivotably (openably) attached to the rear end portion 11 of the first housing 5 by the hinges 4a and 4b. In this way, the display unit 3 can pivot between a first position where it overlaps the main unit 2 and a second position where it is open relative to the main unit 2.

As illustrated in FIGS. 1 and 2, the second housing 15 includes a front wall 17, a back wall 18, and a circumferential wall 19. The front wall 17 faces the main unit 2 when the display unit 3 is at the first position. The front wall 17 includes an opening 17a through which the display screen 16a of the display device 16 is exposed. In other words, the second housing 15 can pivot between the first position where the display screen 16a is covered by the first housing 5 and the second position where the display screen 16a is exposed.

The back wall 18 extends substantially in parallel to the front wall 17 with a space between the front wall 17 and the back wall 18. The back wall 18 faces the display device 16 on a side opposite to the front wall 17. The circumferential wall 19 stands on the back wall 18 and connects the edge of the front wall 17 with the edge of the back wall 18.

Next, a hard disk drive accommodating portion 21 will be described. In the following description, the hard disk drive accommodating portion 21 will be referred to as an “HDD accommodating portion 21,” and the first housing 5 will be simply referred to as a “housing 5.”

As illustrated in FIGS. 2 to 9, the HDD accommodating portion 21 is provided on the lower wall 7 of the housing 5. The HDD accommodating portion 21 is a depression which is recessed from the lower wall 7 toward the inner side of the housing 5. The HDD accommodating portion 21 accommodates a hard disk drive unit 22 (hereinafter referred to as an HDD unit 22). The HDD accommodating portion 21 is an example of an “accommodating portion.” The HDD unit 22 is an example of a “unit.”

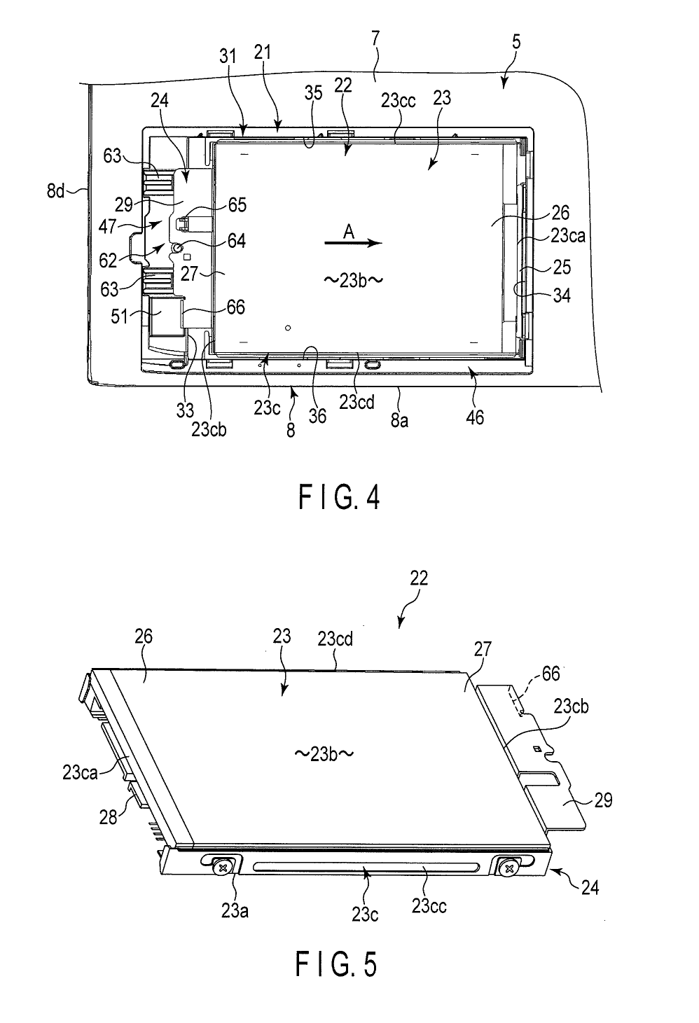

As illustrated in FIGS. 4 and 5, the HDD unit 22 includes a hard disk drive 23 (hereinafter referred to as an HDD 23) and a holder 24 that holds the HDD 23. The HDD 23 is an example of a “module,” an example of an “accommodated component,” and an example of a “storage medium.” The holder 24 is an example of an “attachment member” and is formed of metal, for example.

The HDD 23 is flat and rectangular in shape and includes first and second principal surfaces 23a and 23b having a relatively large size, and a circumferential surface 23c. The first and second principal surfaces 23a and 23b are surfaces that extend substantially in parallel to the surface of a magnetic disc inside the HDD 23. The circumferential surface 23c stands on the first and second principal surfaces 23a and 23b and connects the edge of the first principal surface 23a and the edge of the second principal surface 23b. The circumferential surface 23c includes a front surface 23ca, a rear surface 23cb, a first side surface 23cc (left side surface), and a second side surface 23cd (right side surface).

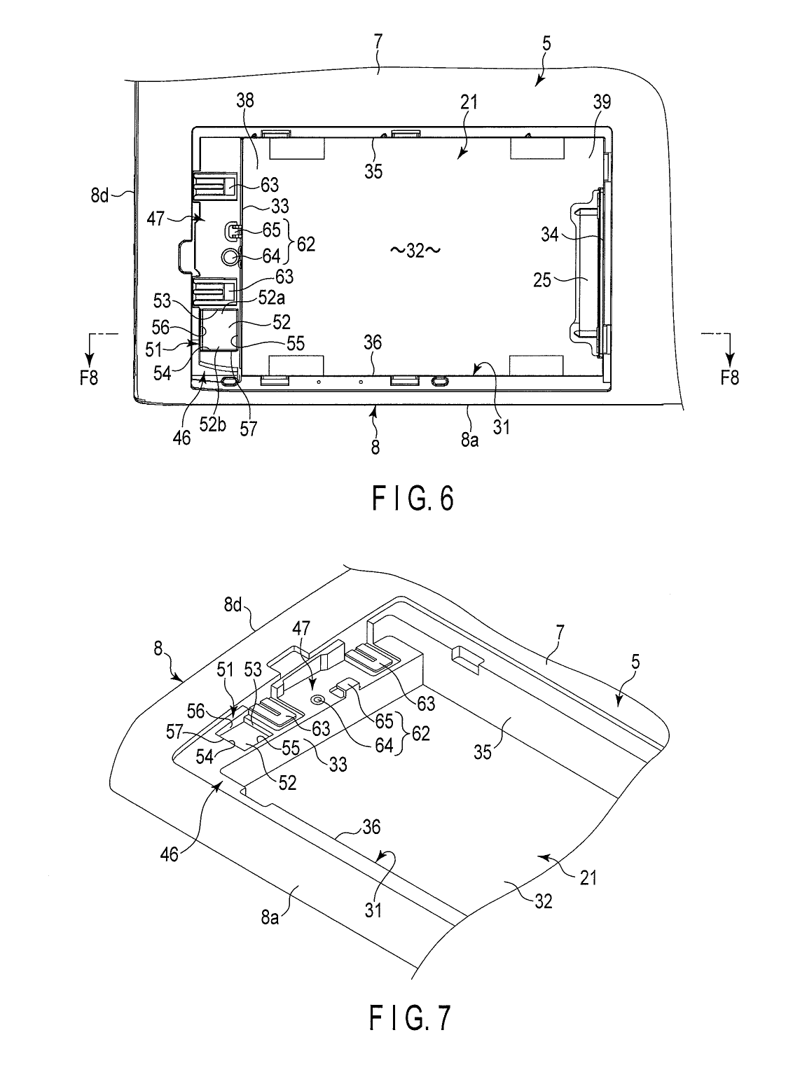

Here, as illustrated in FIGS. 4 and 6, a connector 25 is provided in the end portion of the HDD accommodating portion 21. The HDD unit 22 is attached to the HDD accommodating portion 21 in a way of inserting the HDD unit 22 into the HDD accommodating portion 21 substantially in a vertical direction and then sliding the HDD unit 22 in the direction indicated by the arrow A in FIG. 4. In this way, the HDD unit 22 is connected to the connector 25 of the HDD accommodating portion 21.

In this specification, the front, rear, left, and right are defined based on the sliding direction of the HDD unit 22. That is, the side on which the connector 25 is located as seen from the HDD unit 22 is defined as “front” and the side opposite to the connector 25 is defined as “rear.”

As illustrated in FIG. 5, the HDD unit 22 includes first and second end portions 26 and 27 which are the end portions in the longitudinal direction thereof. A connector 28 of the HDD 23 is provided on the first end portion 26. The connector 28 of the HDD 23 is directly connected (namely, fitted) to the connector 25 of the HDD accommodating portion 21 and electrically connected to the connector 25. An extension portion 29 of the holder 24 is provided on the second end portion 27.

As illustrated in FIGS. 6 to 9, the HDD accommodating portion 21 has a substantially rectangular shape and is slightly larger than the HDD 23, for example. The HDD accommodating portion 21 includes an opening 31 leading to the outside, and the inside of the HDD accommodating portion 21 is exposed to the outside through the opening 31.

The HDD accommodating portion 21 includes a receiving wall 32 (bottom wall, ceiling wall) and first to fourth walls 33, 34, 35, and 36 which are standing walls that stand on the periphery of the receiving wall 32. The receiving wall 32 is an example of a “first receiving wall.” The receiving wall 32 extends substantially in parallel to the HDD 23, for example, and faces the first principal surface 23a of the HDD 23. The receiving wall 32 has an area slightly larger than the first principal surface 23a of the HDD 23.

The first to fourth walls 33, 34, 35, and 36 stand on different edges of the receiving wall 32 and extend from the receiving wall 32 toward the lower wall 7 in the thickness direction of the housing 5. The first to fourth walls 33, 34, 35, and 36 extend further than the thickness of the HDD 23 and define a space capable of accommodating the HDD 23 therein. The first to fourth walls 33, 34, 35, and 36 collaborate with each other to surround the HDD 23 from four directions and define the opening 31 (HDD accommodating opening).

As illustrated in FIGS. 6 to 9, the first wall 33 stands on the rear edge of the receiving wall 32 and faces the rear surface 23cb of the HDD 23. The first wall 33 is an example of a “first standing wall” and a “wall” constituting a part of the accommodating portion. The second wall 34 stands on the front edge of the receiving wall 32 and faces the front surface 23ca of the HDD 23. The first and second walls 33 and 34 extend in the lateral direction of the housing 5 substantially in parallel to each other.

The HDD accommodating portion 21 includes a first end portion 38 at which the first wall 33 is formed, and a second end portion 39 which is located on a side opposite to the first end portion 38 and at which the second wall 34 is formed. The connector 25 described above is provided at the second end portion 39. The first wall 33 is disposed opposite to the connector 25 in the HDD accommodating portion 21, and is located farther from the connector 25 than the HDD 23. The first wall 33 is a wall which is furthest from the connector 25 among the four walls 33, 34, 35, and 36.

The third wall 35 stands on the left edge of the receiving wall 32 and faces the first side surface 23cc of the HDD 23. The fourth wall 36 stands on the right edge of the receiving wall 32 and faces the second side surface 23cd of the HDD 23. The third and fourth walls 23cc and 23cd extend in the longitudinal direction of the housing 5 substantially in parallel to each other.

As illustrated in FIG. 9, an HDD cover 41 is attached to the housing 5. The HDD cover 41 detachably covers the HDD accommodating portion 21. The housing 5 is an example of a “first member.” The HDD cover 41 is an example of a “cover” and a “second member.” The HDD cover 41 includes a first surface 42 that is exposed to the outside of the housing 5, and a second surface 43 that is located on the opposite side of the first surface 42 and faces the HDD accommodating portion 21.

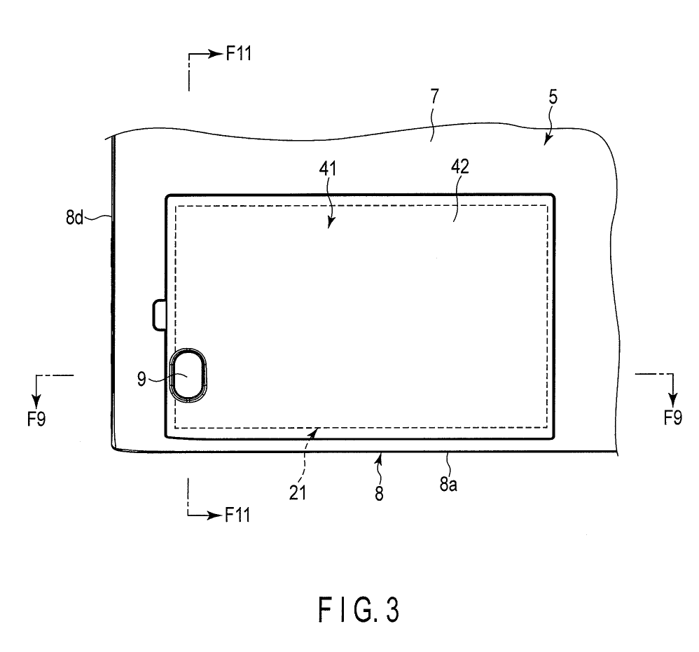

As illustrated in FIGS. 2 and 3, the first surface 42 of the HDD cover 41 is disposed substantially on the same plane as the lower wall 7 of the housing 5 and is continuous to the lower wall 7. The same leg 9 as those of the lower wall 7 is provided on the first surface 42 of the HDD cover 41. When the electronic apparatus 1 is placed on the desk, the leg 9 contacts the surface of the desk to support the electronic apparatus 1. The leg 9 is an example of a “supporting portion” and a “protrusion on the first surface.”

As illustrated in FIGS. 9 to 11, ribs 44 are formed on the second surface 43 of the HDD cover 41. The rib 44 is an example of a “protrusion (protrusion on the second surface)” and protrudes from the second surface 43 in the thickness direction of the housing 5. In addition, the “protrusion” is not limited to the rib, and may be a boss, for example, and have other shapes.

The ribs 44 are disposed on the second surface 43 at a location corresponding to at least a part of the leg 9. That is, the ribs 44 are disposed on the side (rear side) opposite to at least a part of the leg 9. In addition, the “corresponding location” means that two elements overlap (namely, face) each other in the thickness direction of the HDD cover 41. When the electronic apparatus 1 is placed on the surface of a desk, at least a part of the leg 9 is located right below the rib 44.

As illustrated in FIG. 12, the ribs 44 include a first portion 44a and a second portion 44b. The first portion 44a extends in the longitudinal direction of the HDD cover 41. The second portion 44b extends in the lateral direction of the HDD cover 41. That is, the second portion 44b extends in a direction crossing (for example, substantially perpendicular to) the first portion 44a. The first and second portions 44a and 44b cross each other and are connected to each other, so that the ribs 44 are formed in a grid shape. With this configuration, it is possible to provide the ribs 44 which are superior in strength and are light.

As illustrated in FIGS. 6 to 11, a mounting portion 46 on which the HDD cover 41 is placed is formed in the housing 5. The mounting portion 46 is provided at the periphery of the HDD accommodating portion 21 and is recessed from the lower wall 7 by an amount corresponding to the thickness of the HDD cover 41. When the HDD cover 41 is placed on the mounting portion 46, the first surface 42 of the HDD cover 41 is located substantially on the same plane as the surface of the lower wall 7. Moreover, an attachment portion 47 that faces the extension portion 29 of the holder 24 of the HDD unit 22 is formed on the housing 5. The attachment portion 47 has a larger width than the mounting portion 46. The attachment portion 47 is adjacent to the first wall 33. The attachment portion 47 is a part of the HDD accommodating portion 21, for example.

As illustrated in FIGS. 6 to 11, a receiving portion 51 that receives the ribs 44 of the HDD cover 41 when stress is applied from the outside, for example, is provided on the housing 5. The receiving portion 51 is a recess on the attachment portion 47 and is recessed toward the inside of the housing 5. The receiving portion 51 is formed at the location corresponding to the ribs 44 of the HDD cover 41, namely at the location facing the ribs 44 in the protruding direction of the ribs 44. In the following description, for convenience's sake, the first wall 33 of the HDD accommodating portion 21 will be referred to as a “first standing wall 33.”

The receiving portion 51 includes a receiving wall 52 (bottom wall, ceiling wall) and first to fourth walls 53, 54, 55, and 56 which are standing walls that stand on the periphery of the receiving wall 52. The receiving wall 52 is an example of a “second receiving wall.” The receiving wall 52 faces the ribs 44 in the protruding direction of the ribs 44. The receiving wall 52 has a plane that extends in the direction crossing (for example, substantially perpendicular to) the protruding direction of the ribs 44. The receiving wall 52 extends substantially in parallel to the receiving wall 32 of the HDD accommodating portion 21.

The first to fourth walls 53, 54, 55, and 56 stand on different edges of the receiving wall 52 and extend from the receiving wall 52 toward the lower wall 7 in the thickness direction of the housing 5. The first to fourth walls 53, 54, 55, and 56 define an opening 57 that leads the receiving portion 51 to the outside. The first to fourth walls 53, 54, 55, and 56 connect the receiving wall 52 and the attachment portion 47. The first to fourth walls 53, 54, 55, and 56 are configured such that adjacent walls are connected to each other.

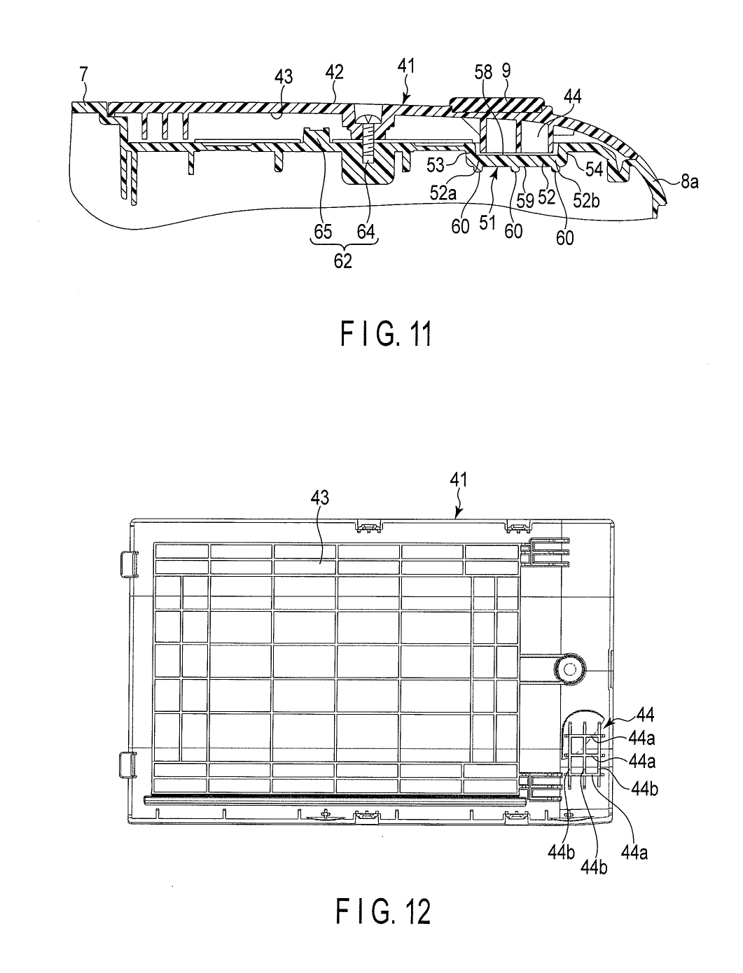

As illustrated in FIGS. 6 and 11, the receiving wall 52 includes a first end portion 52a and a second end portion 52b located on a side opposite to the first end portion 52a. The first wall 53 stands on the first end portion 52a. The second wall 54 stands on the second end portion 52b. The first wall 53 is an example of a “second standing wall.” The second wall 54 is an example of a “fourth standing wall.”

As illustrated in FIGS. 6 and 7, specifically, the first wall 53 stands on the left edge of the receiving wall 52. The second wall 54 stands on the right edge of the receiving wall 52. The first and second walls 53 and 54 extend in the longitudinal direction of the housing 5 substantially in parallel to each other. The first and second walls 53 and 54 extend toward the first standing wall 33 and are connected to the first standing wall 33 from a direction substantially perpendicular to the first standing wall 33. With this configuration, the receiving wall 52 of the receiving portion 51 is supported by the first standing wall 33 with the first and second walls 53 and 54 located therebetween.

As illustrated in FIGS. 6 to 8, the third wall 55 stands on the front edge of the receiving wall 52. The fourth wall 56 stands on the rear edge of the receiving wall 52. The third and fourth walls 55 and 56 extend in a different direction from the first wall 53, for example, in the lateral direction of the housing 5. The third wall 55 is an example of a “third standing wall.”

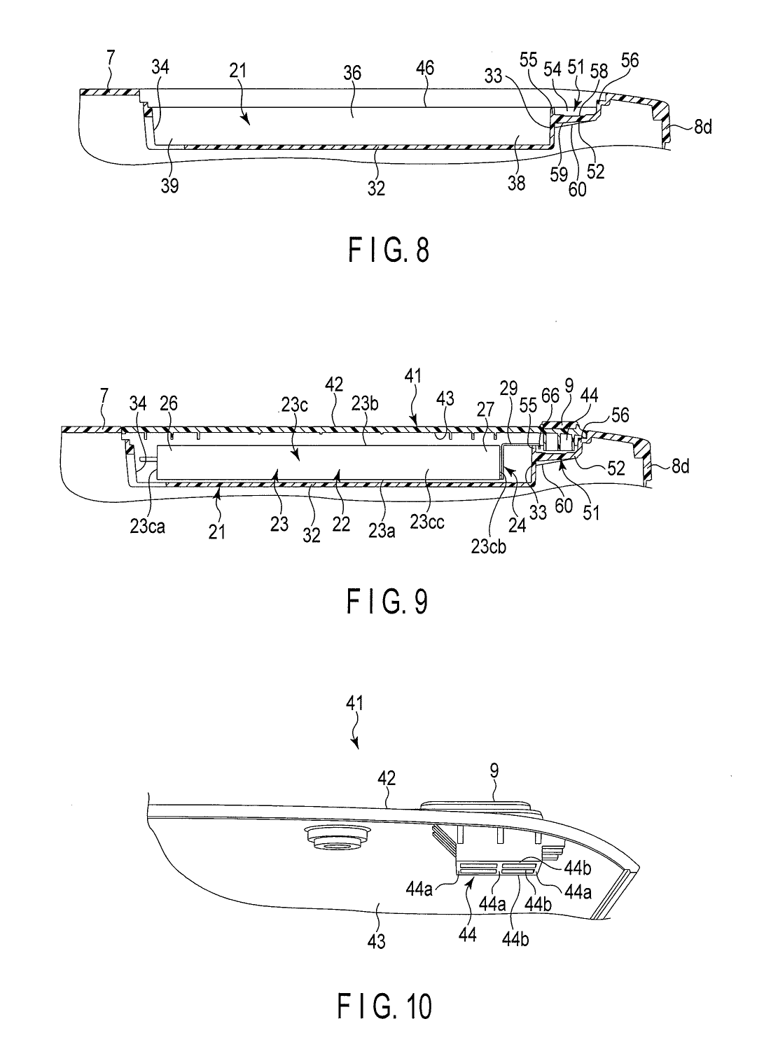

As illustrated in FIG. 8, the receiving portion 51 of the present embodiment is formed adjacent to the HDD accommodating portion 21 and is located near the first standing wall 33. Moreover, the first standing wall 33 of the HDD accommodating portion 21 comprises at least part of a wall that constitutes part of the receiving portion 51 constitutes.

Specifically, the third wall 55 of the receiving portion 51 is formed by part of the first standing wall 33 of the HDD accommodating portion 21. That is, a wall standing between the HDD accommodating portion 21 and the receiving portion 51 forms the first standing wall 33 of the HDD accommodating portion 21 and the third wall 55 of the receiving portion 51.

As illustrated in FIG. 8, the receiving wall 52 of the receiving portion 51 extends substantially in parallel to the receiving wall 32 of the HDD accommodating portion 21 and is directly connected to the first standing wall 33. That is, the receiving wall 52 of the receiving portion 51 is directly supported by the first standing wall 33. The receiving wall 52 includes a first surface 58 that faces the rib 44 of the HDD cover 41 and a second surface 59 located on a side opposite to the first surface 58. The second surface 59 is the inner surface of the housing 5 exposed to the inner side thereof.

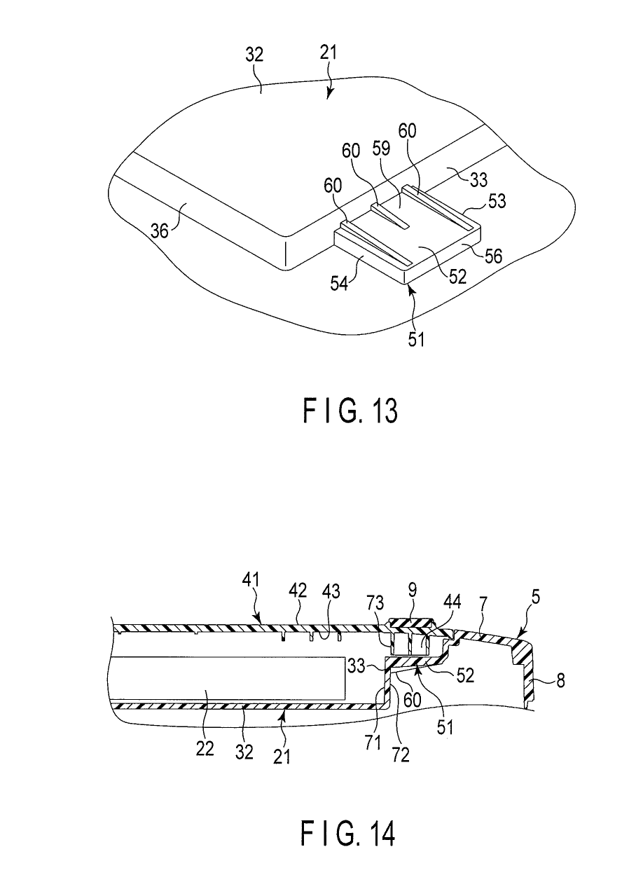

As illustrated in FIGS. 8 and 13, for example, three ribs 60 (second ribs) are formed on the second surface 59 of the receiving wall 52. The ribs 60 protrude from the second surface 59 in the thickness direction of the housing 5. The three ribs 60 are formed at both ends and a central portion of the receiving wall 52, for example. The ribs 60 extend substantially in parallel to the first and second walls 53 and 54. The ribs 60 are directly connected to the first standing wall 33 with the height increasing as they approach the first standing wall 33. The ribs 60 are connected to the first standing wall 33 in the direction crossing (for example, substantially perpendicular to) the first standing wall 33.

As illustrated in FIGS. 9 and 11, the ribs 44 protrude toward the receiving portion 51. The ribs 44 are configured to touch the receiving portion 51 (namely, the housing 5) at the location adjacent to the first standing wall 33 when stress is applied from the outside, for example. In addition, the ribs 44 may always touch the receiving portion 51. Alternatively, the ribs 44 may be normally separated from the receiving portion 51 and come to touch the receiving portion 51 only when stress is applied from the outside.

As illustrated in FIGS. 6 and 7, a fixing portion 62 and a pair of terminals 63 are on the attachment portion 47. The fixing portion 62 includes a screw hole 64 to which the HDD cover 41 is attached by screwing and an engaging portion 65 that engages with the holder 24 of the HDD unit 22. The engaging portion 65 is a hook, for example. The terminal 63 is electrically connected to the ground provided in the housing 5 and touches the holder 24 of the HDD unit 22. In this way, the holder 24 of the HDD unit 22 is electrically connected to the ground of the housing 5.

As illustrated in FIGS. 6 and 7, the receiving portion 51 is located closer to the circumferential wall 8 than the fixing portion 62 and the terminal 63. Specifically, the receiving portion 51 is located closer to the front wall 8a than the fixing portion 62 and the terminal 63, and is supported by the front wall 8a.

As illustrated in FIG. 9, the extension portion 29 of the holder 24 of the HDD unit 22 includes an engaging portion 66 that engages with the receiving portion 51. The engaging portion 66 is formed in a hook-like shape to be received in the receiving portion 51 and faces the third wall 55. When stress is applied to the housing 5 in the horizontal direction, the engaging portion 66 touches the third wall 55, so that movement of the HDD unit 22 toward the connector 25 is suppressed. In this way, the reliability of the HDD unit 22 and the connector 25 improves.

Next, the operation of the electronic apparatus 1 will be described.

When stress (for example, impact) is applied to the leg 9 of the HDD cover 41, the stress is transmitted from the leg 9 to the ribs 44. Moreover, the ribs 44 touch the receiving portion 51, whereby the stress is transmitted from the ribs 44 to the receiving portion 51. The stress transmitted to the receiving portion 51 is further transmitted from the receiving portion 51 to the first standing wall 33 and thus absorbed by the first standing wall 33. In this way, the stress is unlikely to be transmitted to the HDD 23.

With such a configuration, it is possible to improve stress resistance.

When the leg is provided on the HDD cover, stress is likely to be concentrated on the vicinity of the leg of the HDD cover. Meanwhile, the HDD is vulnerable to stress. Therefore, the inventors of the present embodiment conceived a structure in which a receiving portion receiving stress from the HDD cover is provided on the housing. The inventors also conceived a structure in which the receiving portion is separated as far as possible from the HDD accommodating portion which is supposed not to receive the stress transmitted. However, the inventors found that if the receiving portion is separated from the HDD accommodating portion, stress is distributed in various paths within the housing, and part of the stress is transmitted to the HDD.

On the other hand, the electronic apparatus of the present embodiment includes the housing 5 having the accommodating portion 21 which is open to the outside and in which a module 23 is accommodated, the wall 33 which is formed in the housing 5 so as to constitute a part of the accommodating portion 21 and extend in the thickness direction of the housing 5, the cover 41 having the first surface 42 exposed to the outside and the second surface 43 located on the opposite side of the first surface 42 and covering the accommodating portion 21, and the protrusion 44 provided on the second surface 43 of the cover 41 so as to touch the housing 5 at the location adjacent to the wall 33.

That is, in this structure, the protrusion 44 of the cover 41 touches the housing 5 at the location adjacent to the wall 33 of the accommodating portion 21. Here, since the wall 33 of the accommodating portion 21 extends in the thickness direction of the housing 5, which is the input direction of stress, it is possible to absorb the stress without large elastic deformation even when stress is applied thereto. Thus, the stress applied to the cover 41 escapes from the protrusion 44 of the cover 41 to converge on the wall 33 of the accommodating portion 21 and is absorbed by the wall 33. Therefore, stress is not nearly distributed within the housing 5, and the stress reaching the HDD 23 decreases. In other words, in the above-described structure, a stress transmission path along which stress escapes from the protrusion 44 of the cover 41 to the wall 33 of the accommodating portion 21 is actively, intentionally provided. Thus, stress is hardly transmitted to the HDD 23.

In the present embodiment, the leg 9 is on the first surface 42 of the cover 41, and the ribs 44 are on the second surface 43. The ribs 44 are on the second surface 43 at the location corresponding to at least a part of the leg 9. Thus, stress applied to the leg 9 of the cover 41 is easily transmitted to the ribs 44. Therefore, it is possible to transmit stress more effectively.

In the present embodiment, the receiving portion 51 is recessed toward the inner side of the housing 5. With this configuration, it is possible to decrease the thickness of the housing 5 having a structure in which the ribs 44 protrude from the cover 41.

In the present embodiment, the receiving portion 51 includes the receiving wall 52 facing the ribs 44 and the first wall 53 which stands on the edge of the receiving wall 52 in the thickness direction of the housing 5 and is connected to the first standing wall 33. In the following description, for convenience in description, the first wall 53 will be referred to as a “second standing wall 53.” The second standing wall 53 standing in the thickness direction of the housing 5 which is the input direction of stress can securely receive stress without large elastic deformation. Since stress is transmitted from the second standing wall 53 to the first standing wall 33, it is possible to transmit stress to the first standing wall 33 more effectively.

In the present embodiment, the receiving portion 51 is located near the first standing wall 33, and the first standing wall 33 comprises the wall 55 constituting a part of the receiving portion 51 constitutes. That is, since a part of the receiving portion 51 is formed by the first standing wall 33, the stress transmitted to the receiving portion 51 can be transmitted to the first standing wall 33 more effectively. Moreover, if the receiving portion 51 is located near the first standing wall 33, it is possible to decrease the size of the electronic apparatus 1 as compared to when a gap is between the receiving portion 51 and the first standing wall 33.

In the present embodiment, the receiving portion 51 includes the third wall 55 extending in a different direction from the second standing wall 53. In the following description, for convenience in description, the third wall 55 will be referred to as a “third standing wall 55.” The third standing wall 55 is formed by a part of the first standing wall 33. That is, since a part of the receiving portion 51 is formed by the first standing wall 33, the stress applied to the receiving portion 51 can be transmitted to the first standing wall 33 more effectively.

In the present embodiment, the second standing wall 53 is connected to the first standing wall 33 substantially in a perpendicular direction. If the first and second standing walls 33 and 53 are substantially perpendicular to each other, a supporting portion having a T-shaped section is formed by the first and second standing walls 33 and 53. Accordingly, it is possible to receive and transmit stress more effectively.

In the present embodiment, the receiving portion 51 includes the first end portion 52a on which the second standing wall 53 stands and the second end portion 52b located on a side opposite to the first end portion 52a. Moreover, the receiving portion 51 includes the second wall 54 which stands on the second end portion 52b, extends substantially in parallel to the second standing wall 53, and is connected to the first standing wall 33. In the following description, for convenience in description, the second wall 54 will be referred to as a “fourth standing wall 54.” With this configuration, since the second and fourth standing walls 53 and 54 are connected in the direction substantially perpendicular to the first standing wall 33, and two supporting portions each having a T-shaped section are formed by the first, second and fourth standing walls 33, 53, and 54, it is possible to receive and transmit stress far more effectively.

In the present embodiment, the receiving wall 52 of the receiving portion 51 is directly connected to the first standing wall 33. Thus, the stress transmitted to the receiving wall 52 of the receiving portion 51 can be transmitted directly to the first standing wall 33. Therefore, it is possible to transmit stress to the first standing wall 33 more effectively.

In the present embodiment, the receiving wall 52 of the receiving portion 51 includes the first surface 58 facing the ribs 44 of the cover 41 and the second surface 59 located on the opposite of the first surface 58, and the ribs 60 connected to the first standing wall 33 are on the second surface 59. If the ribs 60 on the second surface 59 are directly connected to the first standing wall 33, the stress transmission path between the receiving portion 51 and the first standing wall 33 increases in size. Thus, the stress transmitted to the receiving wall 52 of the receiving portion 51 can be transmitted to the first standing wall 33 more effectively.

In the present embodiment, the connector 25 connected to the HDD 23 is provided in the accommodating portion 21, and the first standing wall 33 is located on the opposite side of the accommodating portion 21 from the connector 25. The connector 25 is one of the components which are vulnerable to stress. In the present embodiment, stress escapes to the standing wall 33 which is located farthest from the connector that is vulnerable to stress. Therefore, stress is hardly transmitted to the connector 25, and reliability improves.

In the present embodiment, the receiving portion 51 is located closer to the circumferential wall 8 than the fixing portion 62 and the terminal 63, and is supported by the circumferential wall 8 extending in the thickness direction of the housing 5. With this configuration, part of the stress transmitted to the receiving portion 51 is also absorbed by the circumferential wall 8 and is hardly transmitted to the HDD 23.

Next, several modifications will be described with reference to FIGS. 14 to 17.

FIG. 14 illustrates a first modification. As illustrated in FIG. 14, a receiving portion 51 of this modification is not recessed from a mounting portion 46 but is formed in a planar shape. That is, the receiving portion 51 does not include second and fourth standing walls 53 and 54 connected to a first standing wall 33. Ribs 44 of an HDD cover 41 touch a housing 5 at the location adjacent to the first standing wall 33 (or near the first standing wall 33).

As illustrated in FIG. 14, in the first modification, the first standing wall 33 includes a first surface 71 and a second surface 72. The first surface 71 is exposed to an HDD accommodating portion 21. The second surface 72 is located on the opposite side of the first surface 71 and is exposed to the inside of the housing 5.

An edge 73 (end portion) of the rib 44 of the HDD cover 41 is located at the extension line of the second surface 72 of the first standing wall 33. In addition, the structure in which the edge 73 of the rib 44 is located at the extension line of the second surface 72 of the first standing wall 33 is an example of the structure in which “the protrusion touches the first standing wall.” In this modification, the edge 73 of the rib 44 touches the first standing wall 33.

According to such a configuration, it is possible to improve stress resistance. If at least a part of the rib 44 touches the first standing wall 33, since stress is effectively transmitted from the ribs 44 through the first standing wall 33, the stress resistance of the electronic apparatus 1 improves further.

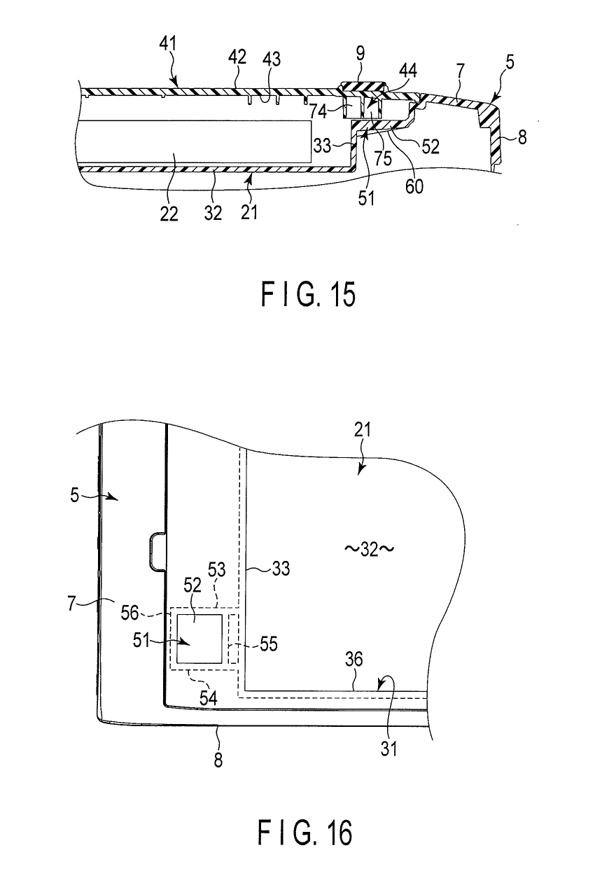

FIG. 15 illustrates a second modification. As illustrated in FIG. 15, a rib 44 of an HDD cover 41 is at the location facing a first standing wall 33. The rib 44 includes a first portion 74 facing the first standing wall 33 and a second portion 75 separated from the first standing wall 33. The first portion 74 directly touches the first standing wall 33. The second portion 75 touches a housing 5 at the location adjacent to the first standing wall 33 (or near the first standing wall 33). In addition, the structure illustrated in FIG. 15 is an example of the structure in which “the protrusion touches the first standing wall,” and the rib 44 touches the first standing wall 33.

According to such a configuration, it is possible to improve stress resistance. Similarly to the first modification, if the rib 44 touches the first standing wall 33, since stress is effectively transmitted from the rib 44 through the first standing wall 33, the stress resistance of the electronic apparatus 1 improves further.

FIG. 16 illustrates a third modification. As illustrated in FIG. 16, a third wall 55 of a receiving portion 51 is separated from a first standing wall 33 and is provided independently from the first standing wall 33. A receiving wall 52 of the receiving portion 51 is not connected to the first standing wall 33. On the other hand, second and fourth standing walls 53 and 54 extend up to the first standing wall 33 over the third standing wall 55 and are connected to the first standing wall 33.

According to such a configuration, it is possible to improve stress resistance. That is, with the second and fourth standing walls 53 and 54, the stress transmitted to the receiving portion 51 can be effectively transmitted to the first standing wall 33. In this way, it is possible to decrease the stress applied to an HDD 23.

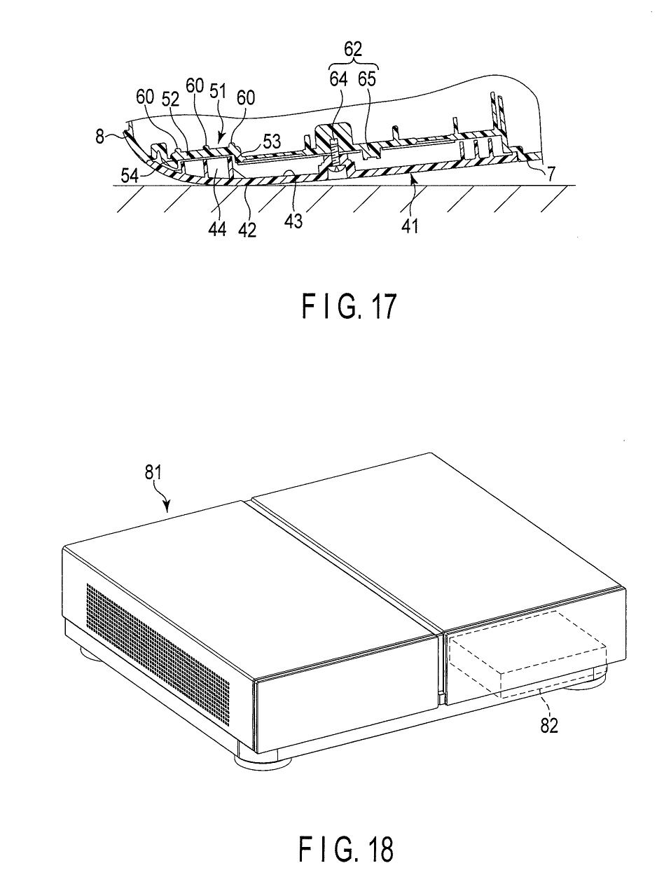

FIG. 17 illustrates a fourth modification. As illustrated in FIG. 17, a cover 41 of the fourth modification does not include a leg 9, and a first surface 42 of the cover 41 directly touches a surface S of the desk. With such a configuration, by making the other configurations the same as those of the first embodiment, the stress applied to the cover 41 can be effectively transmitted to a first standing wall 33. Thus, the stress resistance of the electronic apparatus 1 can be improved.

### Second Embodiment

Next, a television 81 according to a second embodiment will be described with reference to FIG. 18. Configurations having the same or similar functions as those of the configurations of the first embodiment will be denoted by the same reference numerals, and description thereof will not be repeated. Moreover, configurations other than those described below are the same as those of the first embodiment.

As illustrated in FIG. 18, the television 81 is a television connecting device, for example, and is used by being connected to a display device such as a liquid crystal display device. The television 81 includes a box-shaped housing 5. The housing 5 includes a stress transmission structure 82. The stress transmission structure 82 is the same as the structure near the HDD of the first embodiment. That is, the stress transmission structure 82 includes an accommodating portion 21, a module (an HDD 23), and a cover 41 which are the same as those of the first embodiment. The stress transmission structure 82 can allow stress applied to the cover 41 to escape to a wall 33 that constitutes a part of the accommodating portion 21. With this configuration, the television 81 of the present embodiment can improve the stress resistance similarly to the first embodiment.

The embodiment is not limited to the embodiments described above but may be realized by modifying constituent elements in the implementing stage within a range without departing from the spirit of the invention. Moreover, various embodiments can be made by appropriately combining a plurality of constituent elements disclosed in the embodiments described above. For example, some constituent elements may be omitted from all the constituent elements disclosed in the embodiments. Furthermore, constituent elements in different embodiments may be combined appropriately.

For example, the “module” is not limited to the HDD 23 but may appropriately be various components mounted on the electronic apparatus or the television. At least a part of each of the first to fourth standing walls 33, 53, 54, and 55 may extend in the thickness direction of the housing 5. The “first member” and the “second member” may not be detachable from each other but may be attached to each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing comprising an accommodating portion comprising an opening and a first wall that defines a part of the opening and extends in a thickness direction of the housing, the accommodating portion being configured to accommodate a hard disk drive;
a cover configured to cover the accommodating portion and comprising an outer first surface and a second surface opposite the first surface, the first surface comprising a leg, the second surface comprising a protrusion at a location corresponding to at least a part of the leg; and
a receiving portion on the housing comprising a receiving wall and an second wall, the receiving wall being recessed toward an inside of the housing and configured to face the protrusion, the second wall standing from a first edge of the receiving wall in the thickness direction of the housing and being connected to the first wall, the receiving portion being configured to receive the protrusion.

2. The television of claim 1,
wherein the receiving portion is located adjacent to the first standing wall, and a part of the receiving portion is a part of the first wall.

3. The television of claim 1,
wherein the second wall extends substantially perpendicular to the first standing wall, and
the receiving portion comprises a third wall extending from a second edge of the receiving wall in the thickness direction of the housing and in a direction different from a direction in which the second wall extends, the third standing wall being a part of the first standing wall.

4. The television of claim 3,
wherein the receiving portion comprises a third edge opposite the first edge, and a fourth wall extending from the third edge and substantially parallel to the second wall and connected to the first wall.

5. The television of claim 1,
wherein the receiving wall is connected to the first wall.

6. The television of claim 1,
wherein the receiving wall comprises a first surface configured to face the protrusion and a second surface opposite the first surface and comprising a rib connected to the first wall.

7. The television of claim 1,
wherein the accommodating portion comprises a connector configured to be connected to the hard disk drive, and
the first wall is on a side opposite the connector in the accommodating portion and is located farther from the connector than the hard disk drive.

8. The television of claim 1, further comprising a metal holder configured to hold the hard disk drive,
wherein the housing comprises a circumferential wall which at least partially extends in the thickness direction of the housing, a fixing portion to which the cover is configured to be fixed, and a terminal configured to be electrically connected to a ground of the housing and touch the holder, and
the receiving portion is closer to the circumferential wall than the fixing portion and the terminal and is supported by the circumferential wall.

9. An electronic apparatus comprising:
a first member comprising a wall extending in a thickness direction of the first member;
a second member configured to be attached to the first member and comprising a first surface exposed to an outside and a second surface opposite the first surface; and
a protrusion on the second surface configured to touch the first member at a location adjacent to the wall.

10. An electronic apparatus comprising:
a housing comprising an accommodating portion configured to accommodate a module, the accommodating portion comprising a wall extending in a thickness direction of the housing;
a cover configured to cover the accommodating portion and comprising an outer first surface and a second surface opposite the first surface; and
a protrusion on the second surface configured to touch the housing at a location adjacent to the wall.
